(19) United States
(12) Patent Application Publication
(10) Pub. No.: US 2014/0116753 A1
(43) Pub. Date: May 1, 2014

(54) WIRING BOARD AND METHOD OF MANUFACTURING THE SAME

(71) Applicant: SAMSUNG ELECTRO-MECHANICS CO., LTD., Suwon (KR)

(72) Inventors: Han Ul LEE, Suwon (KR); Yong Sam LEE, Suwon (KR); Suk Hwan AHN, Suwon (KR)

(73) Assignee: SAMSUNG ELECTRO-MECHANICS CO., LTD., Suwon (KR)

(21) Appl. No.: 13/745,047

(22) Filed: Jan. 18, 2013

(30) Foreign Application Priority Data
Oct. 26, 2012 (KR) 10-2012-0119644

(51) Int. Cl. H05K 3/46; H05K 1/02

(52) U.S. Cl. CPC H05K 3/467; H05K 1/0298
USPC 174/250; 427/97.3; 427/97.4

(57) ABSTRACT

There are provided a wiring board in which plating layers constituting wiring patterns are formed to have uniform thicknesses, and a method of manufacturing the wiring board. The wiring board includes an insulating layer; and wiring patterns formed on the insulating layer, wherein at least one of the wiring patterns is formed by stacking two or more plating layers.

### CROSS-REFERENCE TO RELATED APPLICATIONS

This application claims the priority of Korean Patent Application No. 10-2012-0119644 filed on Oct. 26, 2012, in the Korean Intellectual Property Office, the disclosure of which is incorporated herein by reference.

### BACKGROUND OF THE INVENTION

1. Field of the Invention

The present invention relates to a wiring board and a method of manufacturing the same, and more particularly, to a wiring board in which wiring patterns have uniform thicknesses and a method of manufacturing the same.

2. Description of the Related Art

In the development of miniaturized, lightweight electronic devices, various types of wiring boards have been used.

In general, a wiring board is prepared by forming a pattern layer on an insulating layer. In this regard, generally, the pattern layer is formed by using a method in which an opening corresponding to a pattern shape is formed in the insulating layer via stacking, exposing, and developing processes using a dry film resist and then the opening is filled via a plating process.

However, in a wiring board according to the related art, during a plating process, current density is relatively high in a region in which an interval between an anode and a substrate is narrow or a region in which an area of the anode is large as compared to an area of a substrate . In addition, a portion having high current density has a high plating thickness. Accordingly, when a wiring board is viewed as a whole, plating thicknesses are different according to portions of the substrate on which they are disposed.

In this regard, there is a need for a wiring board having a uniform plating thickness and a method of manufacturing the wiring board.

### RELATED ART DOCUMENT

Korean Patent Laid-Open Publication No. 2010-0068737

### SUMMARY OF THE INVENTION

An aspect of the present invention provides a wiring board in which plating layers constituting wiring patterns are formed to have uniform thicknesses and a method of manufacturing the wiring board.

According to an aspect of the present invention, there is provided a wiring board including an insulating layer; and wiring patterns formed on the insulating layer, wherein at least one of the wiring patterns is formed by stacking two or more plating layers.

The plating layers may include a first plating layer formed on the insulating layer; and a second plating layer formed on the first plating layer.

At least two of the wiring patterns may have interfaces between the first plating layer and the second plating layer, positioned in different positions.

The first plating layer and the second plating layer may be formed of the same material.

According to another aspect of the present invention, there is provided a wiring board including: an insulating layer; and wiring patterns including a first plating layer formed on the insulating layer and a second plating layer formed on the first plating layer, wherein at least two of the wiring patterns respectively have the first plating layer having a different thickness.

According to another aspect of the present invention, there is provided a method of manufacturing a wiring board, the method including: forming a first plating layer on an insulating layer; positioning a mask on the first plating layer; and forming a second plating layer on the first plating layer.

The forming of the first plating layer may include forming a metal seed layer on the insulating layer; and coating a dry film resist on the metal seed layer to form openings along the wiring patterns.

The positioning of the mask may include positioning a dry film resist having a sheet form on the second plating layer; and forming a through portion in the dry film resist.

The forming of the through portion may include forming the through portion above the first plating layer according to a thickness of the first plating layer.

The through portion may be formed to have a size that is reduced as the thickness of the first plating layer is increased.

In the forming of the through portion, when the thickness of the first plating layer is a threshold thickness or more, the through portion may be omitted.

The through portion may be formed to have a circular through hole shape.

The through portion may be formed to have a lattice shape.

The through portion may be formed by arranging a plurality of slits in parallel to each other.

The through portion may be formed to have an area greater than that of the second plating layer.

The method may further include removing the mask.

According to another aspect of the present invention, there is provided a method of manufacturing a wiring board, the method including: forming a plurality of first plating layers having different thicknesses on an insulating layer; positioning a mask on the plurality of first plating layers; and forming a plurality of second plating layers having different thicknesses on the plurality of first plating layers.

The plurality of first plating layers and the plurality of second plating layers may constitute wiring patterns, and the wiring patterns may be formed on the insulating layer to have similar overall thicknesses.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic cross-sectional view of a wiring board according to an embodiment of the present invention;

FIG. 2 is an enlarged cross-sectional view of portion A of FIG. 1;

FIGS. 3 to 10 are cross-sectional views illustrating a method of manufacturing a wiring board, according to an embodiment of the present invention;

FIG. 11 is a schematic plan view of a mask, according to an embodiment of the present invention; and

FIGS. 12 and 13 are schematic plan views of a mask, according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

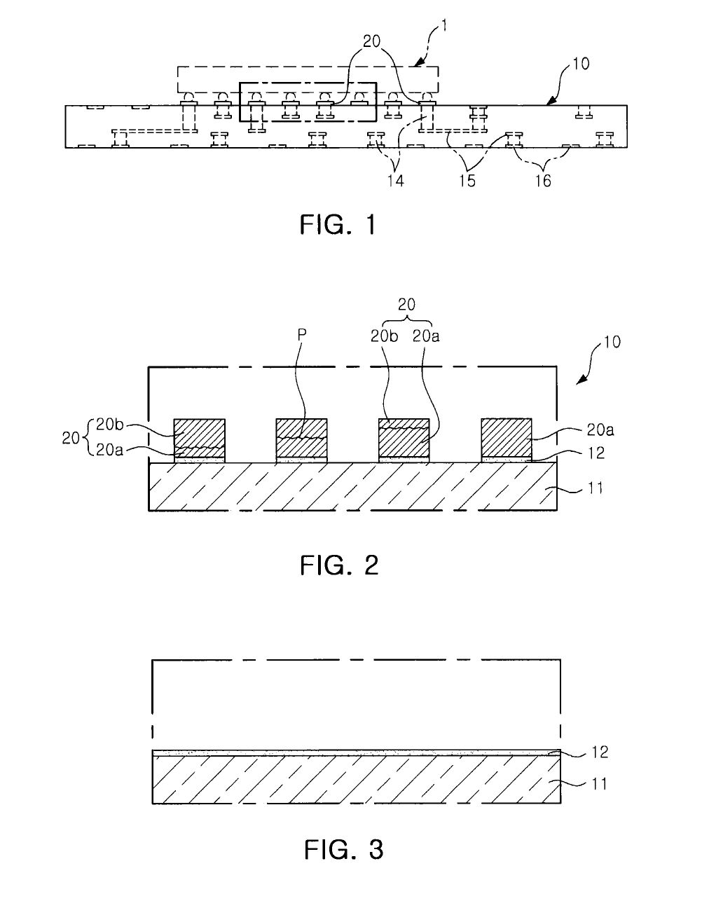

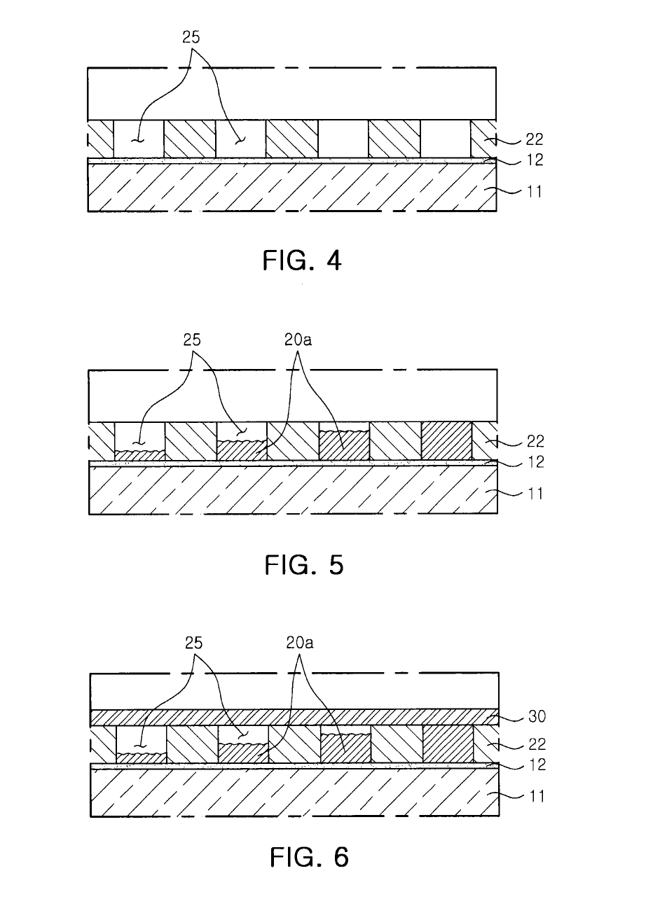

FIG. 1 is a schematic cross-sectional view of a wiring board 10 according to an embodiment of the present invention. FIG. 2 is an enlarged cross-sectional view of portion A of FIG. 1.

Referring to FIGS. 1 and 2, the wiring board 10 according to the present embodiment may be various types of substrate (e.g., a ceramic substrate, a printed circuit board, a flexible substrate, a glass substrate, a pre-molded substrate, or a direct bonded copper (DBC) substrate) well known in the art. In addition, mounting electrodes for mounting an electronic device 1 thereon and various types of wiring patterns 20 for electrically connecting the mounting electrodes to each other maybe formed on both surfaces of the wiring board 10. In this regard, the mounting electrodes may be integrated with the wiring patterns 20 or the wiring patterns 20 may extend to form the mounting electrodes. Thus, hereinafter, the wiring patterns 20 may refer to including mounting electrodes.

The wiring board 10 according to the present embodiment may include a multi-layered board including a plurality of layers. A plurality of circuit patterns 15 for electrically connecting the layers may be formed between the layers.

The circuit patterns 15 maybe formed by using a general pattern forming method, for example, a chemical vapor deposition (CVD) method or a physical vapor deposition (PVD) method, an electroplating method, or an electroless plating method.

The circuit patterns 15 maybe formed of an electrically conductive material such as a metal. For example, the circuit patterns 15 may include aluminum (Al), an Al alloy, copper (Cu), a Cu alloy, or a combination thereof.

The wiring board 10 according to the present embodiment may include the mounting electrodes 20 formed on an upper surface of the wiring board 10, the circuit patterns 15 formed in the mounting electrodes 20, and conductive vias 14 for electrically connecting the mounting electrodes 20 and the circuit patterns 15. In addition, a cavity (not shown) for accommodating electronic devices 1 therein may be formed in the wiring board 10 according to the present embodiment.

External connection pads 16 maybe formed on one surface of the wiring board 10 according to the present embodiment. External connection terminals (not shown) such as solder balls or solder bumps may be provided as the external connection pads 16.

In particular, according to the present embodiment, the wiring patterns 20 of the wiring board 10 may each include at least two plating layers, that is, first and second plating layers 20a and 20b.

The first plating layer 20a is formed directly on the wiring board 10. In this case, first plating layers 20a may be formed to have different thicknesses (or different heights) according to positions of the wiring patterns 20, as shown in FIG. 2.

According to the present embodiment, the first plating layers 20a of four wiring patterns 20 are formed to have different thicknesses. However, the present invention is not limited thereto. That is, according to the size of the wiring board 10 or shapes of the wiring patterns 20, the first plating layers 20a may be formed in various manners, and for example, may be formed to have similar thicknesses or may be formed to have different thicknesses.

The second plating layer 20b is formed on the first plating layer 20a. The second plating layer 20b according to the present embodiment compensates for the thickness (or the height) of the first plating layer 20a. That is, the second plating layer 20b may be formed to compensate for a deficient thickness in the first plating layer 20a, based on an appropriate thickness of each of the wiring patterns 20.

Thus, second plating layers 20b may also be formed to have different thicknesses, like the first plating layers 20a. In addition, the thickness of the second plating layer 20b may be determined according to the thickness of the first plating layer 20a on which a corresponding one of the second plating layers 20b is plated. For example, when the first plating layer 20a is relatively low, the second plating layer 20b is formed to be relatively high. When the first plating layer 20a is relatively high, the second plating layer 20b is formed to be relatively low.

Accordingly, the wiring patterns 20 according to the present embodiment may respectively have interfaces S between the first plating layers 20a and the second plating layers 20b, positioned in different positions.

According to the present embodiment, the first plating layer 20a and the second plating layer 20b may be formed of the same material. However, the present invention is not limited thereto. That is, the first plating layer 20a and the second plating layer 20b may be formed of different materials, as needed.

According to the present embodiment, each of the wiring patterns 20 includes two plating layers, that is, the first and second plating layers 20a and 20b. However, the present invention is not limited thereto. That is, each of the wiring patterns 20 may include three or more plating layers, as needed.

Like a rightwardmost wiring pattern 20 of FIG. 2, each of the wiring patterns 20 may include the first plating layer 20a only, which will be described below in detail with reference to a method of manufacturing the wiring board 10.

The wiring board 10 according to the embodiment of the present invention is formed by stacking a plurality of plating layers, that is, the first and second plating layers 20a and 20b such that the wiring patterns 20 may have similar overall thicknesses, thereby significantly reducing errors of the wiring board 10.

Next, a method of manufacturing the wiring board 10 will be described with regard to an embodiment of the present invention.

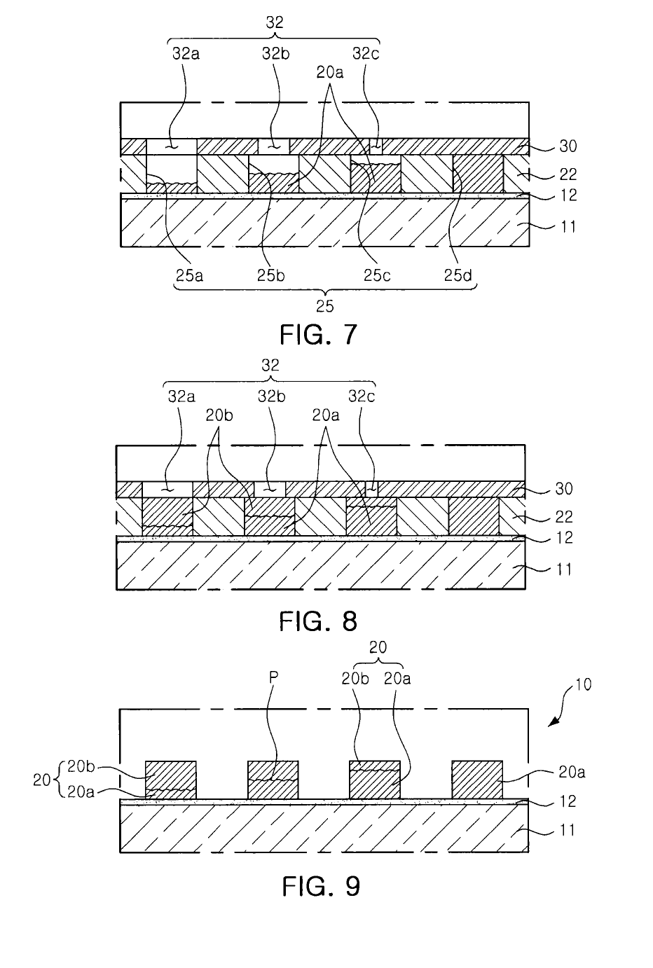

FIGS. 3 to 10 are cross-sectional views illustrating a method of manufacturing the wiring board 10, according to an embodiment of the present invention.

Referring to FIGS. 3 to 10, in the method of manufacturing the wiring board 10, a metal seed layer 12 is formed on an insulating layer 11, as shown in FIG. 3.

The seed layer 12 may be formed on the insulating layer 11 by using a plating process (e.g., electroless plating). The seed layer 12 may be formed of, but is not limited to, a material such as Cu.

Then, as shown in FIG. 4, a dry film resist 22 is coated on the seed layer 12, and then, openings 25 are formed in portions in which the wiring patterns 20 are to be formed, via stacking, exposing, and developing processes.

Then, as shown in FIG. 5, a plating process is performed to form the first plating layers 20a in the openings 25. During this process, the thickness of the first plating layer 20a is affected by an amount of current that is supplied in a plating process. That is, current density is relatively high in a region in which a width (that is, a pattern width) of the opening 25 is relatively narrow or a region in which an interval between an anode electrode and the wiring board 10 is relatively narrow, and thus, plating thicknesses are large in these regions. Accordingly, the first plating layers 20a may have different thicknesses in different openings 25, as shown in FIG. 5.

Then, as shown in FIG. 6, a mask 30 is positioned. The mask 30 may be a dry film resist having a sheet form. However, the present invention is not limited thereto.

The mask 30 is positioned on the openings 25. In this regard, the mask 30 may be positioned to cover an entire upper surface of the wiring board 10 or may be partially positioned on portions of the wiring board 10 corresponding to the openings 25. In addition, the mask 30 may be formed of a material having durability with respect to a plating solution.

Then, as shown in FIG. 7, through portions 32 are formed in the mask 30. The through portions 32 may be formed by photolithography or the like.

The through portions 32 may be formed to correspond to the openings 25, respectively. In addition, according to the present embodiment, the sizes or shapes of the through portions 32 may be determined according to thicknesses of the first plating layers 20a formed in the openings 25.

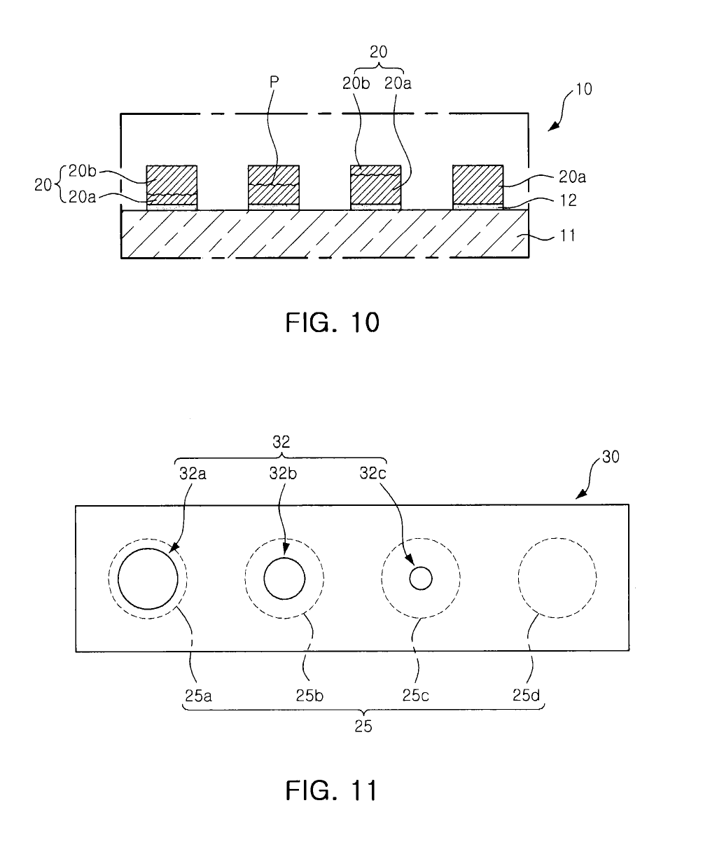

FIG. 11 is a schematic plan view of the mask 30 shown in FIG. 7, according to an embodiment of the present invention. Referring to FIGS. 7 and 11, the mask 30 according to the present embodiment includes the through portions 32 that are holes formed to correspond to the openings 25, respectively.

In addition, the through portions 32 may be formed to correspond to thicknesses of the first plating layers 20a of the openings 25, respectively. That is, a through portion 32c having a smallest hole may be formed in an opening 25c in which the first plating layer 20a has a largest thickness, and a through portion 32a having a largest hole may be formed in an opening 25a in which the first plating layer 20a is lowest.

In a case of an opening 25d in which the first plating layer 20a is sufficient thick, since the wiring pattern 20 is formed to have a threshold thickness or more by the first plating layer 20a only, it is not required to increase the thickness of the wiring pattern 20. Thus, a through portion 32 may not be formed with regard to the corresponding opening 25d.

The present embodiment provides the case in which all of the through portions 32 are formed to have a circular hole shape, but the present invention is not limited thereto. That is, if necessary, the through portions 32 maybe formed to have various shapes.

The through portions 32 are formed in the mask 30, and then, a secondary plating process is performed to complete formation of the wiring patterns 20, as shown in FIG. 8.

As the secondary plating process is performed, the second plating layer 20b, anew plating layer, is formed on the first plating layer 20a. In this case, the second plating layer 20b may also be formed to have different thicknesses, like the first plating layer 20a.

In the secondary plating process, a flow of a plating solution is limited by the through portions 32 formed in the mask 30. That is, since plating-growth is performed at relatively high speed in a portion in which a through portion 32 is formed as a big hole, the second plating layer 20b is formed to be relatively high. Since plating-growth is performed at relatively low speed in a portion in which a through portion 32 is formed as a small hole, the second plating layer 20b is formed to be relatively low.

As described above, from among the through portions 32 according to the present embodiment, the through portion 32c having a smallest hole is formed in the opening 25c in which the first plating layer 20a has a largest thickness. Thus, in this case, the second plating layer 20b is formed to be relatively low. Likewise, the through portion 32a having a largest hole is formed in the opening 25a in which the first plating layer 20a is lowest. Thus, in this case, the second plating layer 20b is formed to be relatively high.

Thus, when the second plating layer 20b is formed, the wiring patterns 20 including the first plating layer 20a or the second plating layer 20b may have approximately the same thickness.

Then, a process of removing the dry film resist 22 is performed as shown in FIG. 9, and a process of removing the seed layer 12 is performed as shown in FIG. 10, thereby completing the manufacture of the wiring board 10 according to the present embodiment.

As described above, in a method of manufacturing a wiring board according to an embodiment of the present invention, two plating processes are performed. From among the two plating processes, a secondary plating process is performed in consideration of a difference in thickness between the wiring patterns 20, which is caused during a primary plating process. Thus, the difference in thickness between the wiring patterns 20, which is caused during a plating process of a method of manufacturing the wiring board 10, may be significantly reduced.

In addition, since the secondary plating process is performed on the wiring board 10 by adjusting the through portions 32 of the mask 30 according to a result of the primary plating process, the plating processes maybe easily performed regardless of the design or shape of the wiring board 10.

Since the method of manufacturing the wiring board 10 according to the present embodiment uses the mask 30, previous plating equipment maybe used. Accordingly, time and costs for replacing the previous plating equipment may be reduced.

A wiring board and a method of manufacturing the same according to the embodiments of the present invention are not limited to the above-described cases, and if necessary, maybe changed in various manners.

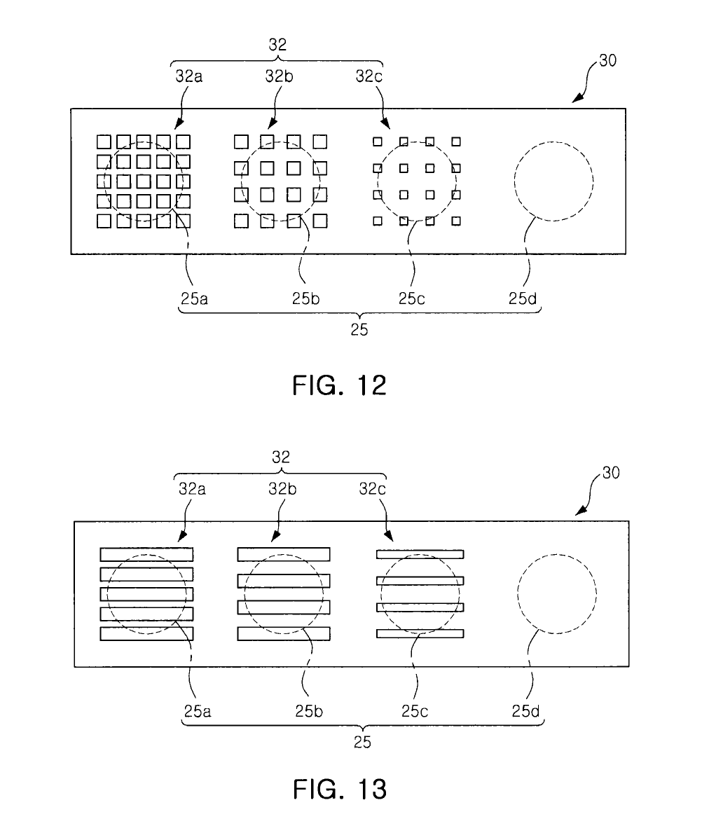

FIGS. 12 and 13 are schematic plan views of the mask 30 shown in FIG. 7, according to another embodiment of the present invention.

First, referring to FIG. 12, the mask 30 according to the embodiment of the present invention may have the through portions 32 having a lattice form. That is, the through portion 32 may include a plurality of through holes.

According to the present embodiment, a growth speed of the second plating layer 20b may be controlled by adjusting a size of each through hole or an interval therebetween.

According to the present embodiment, the through portions 32 are formed to be square. However, the present invention is not limited thereto. That is, the through portions 32 may be changed in various ways, and for example, may be formed to have a circular or polygonal shape.

Referring to FIG. 13, the mask 30 according to the present embodiment may be configured in such a manner that through holes having a slit shape may be arranged in parallel to each other.

According to the present embodiment, a growth speed of the second plating layer 20b may be controlled by adjusting a width of respective slits or an interval therebetween.

According to the present embodiment, the slit is formed linearly. However, the present invention is not limited thereto. That is, the slit may be formed to have various shapes such as a zigzag or a curved shape.

As shown in FIGS. 12 and 13, when the through portions 32 of the mask 30 are each formed by combining a plurality of holes rather than a single hole, even in a case in which the through portions 32 are not aligned with centers of the openings 25, the through portions 32 may have the same effect as in a case in which the through portions 32 are respectively aligned with the centers of the openings 25.

In more detail, in a case of the mask 30 shown in FIG. 11, when the centers of the through portions 32 are accurately aligned with the centers of the openings 25, respectively, the second plating layer 20b may be precisely formed. Thus, it is necessary to precisely control a position of the mask 30.

However, in a case of the mask 30 shown in FIG. 12 or 13, even in a case in which the through portions 32 are respectively formed to be greater than the openings 25, a flow of a plating solution may be controlled according to the size of a lattice or a slit, an interval between lattices or slits, or arrangements of the lattices or the slits. That is, an area of each of the through portions 32 may be greater than an area of each of the openings 25 or the first plating layer 20a. Thus, the mask 30 may be configured in such a manner that the through portions 32 may not be disposed in the openings 25 but the openings 25 may be formed in the through portions 32.

Accordingly, the through portions 32 of the mask 30 and the openings 25 may be easily aligned, and thus, processes may be easily performed.

As set forth above, in a method of manufacturing a wiring board according to an embodiment of the present invention, two plating processes are performed. From among the two plating processes, a secondary plating process is performed in consideration of a difference in thickness between wiring patterns, which is caused during a primary plating process. Thus, the difference in thickness between the wiring patterns, which is caused during a plating process of a method of manufacturing the wiring board, may be significantly reduced.

In addition, since the secondary plating process is performed on the wiring board by adjusting through portions of a mask according to a result of the primary plating process, the plating processes may be easily performed regardless of the design or shape of the wiring board.

Since the method of manufacturing the wiring board according to an embodiment of the present invention uses the mask, previous plating equipment may be used. Accordingly, time and costs for replacing the previous plating equipment may be reduced.

While the present invention has been shown and described in connection with the embodiments, it will be apparent to those skilled in the art that modifications and variations can be made without departing from the spirit and scope of the invention as defined by the appended claims.

What is claimed is:

1. A wiring board comprising:
an insulating layer; and
wiring patterns formed on the insulating layer,
at least one of the wiring patterns being formed by stacking two or more plating layers.

2. The wiring board of claim 1, wherein the plating layers include a first plating layer formed on the insulating layer; and
a second plating layer formed on the first plating layer.

3. The wiring board of claim 2, wherein at least two of the wiring patterns have interfaces between the first plating layer and the second plating layer, positioned in different positions.

4. The wiring board of claim 2, wherein the first plating layer and the second plating layer are formed of the same material.

5. A wiring board comprising:
an insulating layer; and
wiring patterns respectively including a first plating layer formed on the insulating layer and a second plating layer formed on the first plating layer,
at least two of the wiring patterns respectively having the first plating layer having a different thickness.

6. A method of manufacturing a wiring board, the method comprising:
forming a first plating layer on an insulating layer;
positioning a mask on the first plating layer; and
forming a second plating layer on the first plating layer.

7. The method of claim 6, wherein the forming of the first plating layer includes:
forming a metal seed layer on the insulating layer; and
coating a dry film resist on the metal seed layer to form openings along the wiring patterns.

8. The method of claim 7, wherein the positioning of the mask includes:
positioning a dry film resist having a sheet form on the second plating layer; and
forming a through portion in the dry film resist.

9. The method of claim 8, wherein the forming of the through portion includes forming the through portion above the first plating layer according to a thickness of the first plating layer.

10. The method of claim 9, wherein the through portion is formed to have a size that is reduced as the thickness of the first plating layer is increased.

11. The method of claim 9, wherein, in the forming of the through portion, when the thickness of the first plating layer is a threshold thickness or more, the through portion is omitted.

12. The method of claim 9, wherein the through portion is formed to have a circular through hole shape.

13. The method of claim 9, wherein the through portion is formed to have a lattice shape.

14. The method of claim 9, wherein the through portion is formed by arranging a plurality of slits in parallel to each other.

15. The method of claim 13, wherein the through portion is formed to have an area greater than that of the second plating layer.

16. The method of claim 6, further comprising removing the mask.

17. A method of manufacturing a wiring board, the method comprising:
forming a plurality of first plating layers having different thicknesses on an insulating layer;
positioning a mask on the plurality of first plating layers; and
forming a plurality of second plating layers having different thicknesses on the plurality of first plating layers.

18. The method of claim 17, wherein the plurality of first plating layers and the plurality of second plating layers constitute wiring patterns, and the wiring patterns are formed on the insulating layer to have similar overall thicknesses.
